(19) United States
(12) Patent Application Publication
(10) Pub. No.: US 2018/0172733 A1
(43) Pub. Date: Jun. 21, 2018

(54) MAGNETIC ASSEMBLY AND MAGNETIC CORE SET THEREOF

(71) Applicant: DELTA ELECTRONICS, INC., Taoyuan City (TW)

(72) Inventors: Yi-Fan Wu, Taoyuan City (TW); Hsiang-Yi Tseng, Taoyuan City (TW); Tsung-Hsuen Wu, Taoyuan City (TW); Ssu-Wei Fu, Taoyuan City (TW); Hsien-Feng Hung, Taoyuan City (TW)

(21) Appl. No.: 15/655,138

(22) Filed: Jul. 20, 2017

(30) Foreign Application Priority Data
Dec. 21, 2016 (CN) 201611191702.8

(51) Int. Cl. G01R 1/16; H01F 17/04; H01F 27/26; H01F 41/02; H01F 27/28; H05K 1/02; G01R 1/04

(52) U.S. Cl. CPC G01R 1/16; H01F 17/04; H01F 27/26; G01R 1/04; H01F 27/28; H05K 1/02; H01F 41/02

(57) ABSTRACT

A magnetic assembly includes a magnetic core, a magnetic core set, a circuit board and a positioning plate. The magnetic core set includes a first magnetic member, two second magnetic members and a plurality of third magnetic members. A plurality of separation spaces exist between the first magnetic member and two second magnetic members, and the circuit board is disposed between the magnetic core and the magnetic core set. The positioning plate has a first receptacle configured to receive the first magnetic member, two second receptacles each configured to receive one of the second magnetic members, and a plurality of third receptacles configured to receive the third magnetic members. Therefore, the eddy current loss and the winding loss are reduced, the sizes of the separation spaces are controlled precisely, and the advantages of enhancing the effectiveness of the magnetic assembly are achieved.

### CROSS-REFERENCE TO RELATED APPLICATION

This application claims priority from Chinese Patent Application No. CN 201611191702.8, filed on Dec. 21, 2016, the entire contents of which are incorporated herein by reference for all purposes.

### TECHNICAL FIELD

The present disclosure relates to a magnetic assembly, and more particularly to a magnetic assembly and a magnetic core set thereof having a plurality of separation spaces.

### BACKGROUND

In the electronic products, kinds of magnetic assemblies (eg. transformers or inductors) are used to satisfy the required circuit design through the theory of electromagnetic induction. For example, the structure of traditional magnetic assemblies mainly includes a magnetic core assembly, a bobbin and a winding. The winding is wound around the bobbin, and the purpose of the voltage transition is achieved through the electromagnetic induction effect of the magnetic core assembly.

Furthermore, in prior arts, a separation space usually exists between two magnetic cores for avoiding the phenomenon of magnetic saturation. Generally, the separation space is formed by dispensing, such that the separation space is formed at the dispensing position between the magnetic cores while assembling the magnetic assembly.

However, since the separation space is between the magnetic cores, the magnetic lines will cut through the winding when electromagnetic induction effect happens. Consequently, an eddy current loss is caused, and the winding loss is enhanced. In addition, the bobbin has a specific volume, which occupies the winding space of the magnetic assembly, so that it is not easy to reduce the winding loss, hence the effectiveness of the magnetic assembly is decreased. On the other hand, since the separation space is formed by dispensing, the size of the separation space is not easy to control.

Therefore, there is a need of providing a magnetic assembly and a magnetic core set thereof to solve the drawbacks in prior arts, reduce the eddy current loss and the winding loss, precisely control the sizes of the separation spaces, and achieve the advantages of enhancing the effectiveness of the magnetic assembly.

### SUMMARY

It is an object of the present disclosure to provide a magnetic assembly and a magnetic core set thereof in order to solve the drawbacks of prior art.

The present disclosure provides a magnetic assembly and a magnetic core set thereof. By disposing a magnetic core set comprising a first magnetic member, two second magnetic members and a plurality of third magnetic members, and making a plurality of separation spaces exist between the magnetic members, the magnetic lines are prevented from cut through the winding, such that the eddy current loss of the magnetic assembly is reduced.

The present disclosure also provides a magnetic assembly and a magnetic core set thereof. Through disposing the magnetic core set in the receptacles of a positioning plate, the sizes of the separation spaces can be controlled precisely, and the separation spaces are symmetric relative to the first magnetic member of the magnetic core set and uniformly distributed.

The present disclosure also provides a magnetic assembly and a magnetic core set thereof. By disposing a circuit board embedded with a winding between a magnetic core and a magnetic core set, the space in the magnetic assembly occupied by the winding is reduced, and the winding loss is decreased, such that the advantage of enhancing the effectiveness of the magnetic assembly is achieved.

The present disclosure also provides a magnetic assembly and a magnetic core set thereof. Through disposing the detachable bottom part and side walls on the positioning plate, the bottom part and the side walls can be detached after the magnetic assembly is assembled, thereby reducing the volume of the magnetic assembly.

In accordance with an aspect of the present disclosure, there is provided a magnetic assembly. The magnetic assembly comprises a magnetic core, a magnetic core set, a circuit board and a positioning plate. The magnetic core set comprises a first magnetic member, two second magnetic members and a plurality of third magnetic members. The second magnetic members are disposed on two sides of the first magnetic member. The third magnetic members are disposed between the first magnetic member and the two second magnetic members, at least one of the third magnetic members is disposed between the first magnetic member and one of the second magnetic members, at least one of the third magnetic members is disposed between the first magnetic member and the other second magnetic member, and a plurality of separation spaces exist between the first magnetic member and the second magnetic members. The circuit board is disposed between the magnetic core and the magnetic core set, and the positioning plate has a first receptacle, two second receptacles and a plurality of third receptacles. The first receptacle is configured to receive the first magnetic member, each of the two second receptacles is configured to receive one of the second magnetic members, and the third receptacles are configured to receive the third magnetic members.

In accordance with an aspect of the present disclosure, there is provided a magnetic core set. The magnetic core set comprises a first magnetic member, two second magnetic members, and a plurality of third magnetic members. The second magnetic members are disposed on two sides of the first magnetic member. The third magnetic members are disposed between the first magnetic member and the two second magnetic members, at least one of the third magnetic members is disposed between the first magnetic member and one of the second magnetic members, at least one of the third magnetic members is disposed between the first magnetic member and the other second magnetic member, and a plurality of separation spaces exist between the first magnetic member and the second magnetic members.

In accordance with an aspect of the present disclosure, there is provided a magnetic assembly. The magnetic assembly comprises a magnetic core, a magnetic core set, a circuit board and a plurality of separation members. The magnetic core set comprises a first magnetic member, two second magnetic members and a plurality of third magnetic members. The second magnetic members are disposed on two sides of the first magnetic member. The third magnetic members are disposed between the first magnetic member and the two second magnetic members, at least one of the third magnetic members is disposed between the first magnetic member and one of the second magnetic members, at least one of the third magnetic members is disposed between the first magnetic member and the other second magnetic member, and a plurality of separation spaces exist between the first magnetic member and the second magnetic members. The circuit board is disposed between the magnetic core and the magnetic core set, and the separation members are disposed between the first magnetic member and the second magnetic members.

The above contents of the present disclosure will become more readily apparent to those ordinarily skilled in the art after reviewing the following detailed description and accompanying drawings, in which:

### BRIEF DESCRIPTION OF THE DRAWINGS

FIG. 1 schematically illustrates the exploded structure of a magnetic assembly and a magnetic core set thereof according to an embodiment of the present disclosure;

FIG. 2 schematically illustrates the structure of a magnetic assembly and a magnetic core set thereof according to an embodiment of the present disclosure;

FIG. 3 schematically illustrates the exploded structure of a magnetic assembly and a magnetic core set thereof according to another embodiment of the present disclosure;

FIG. 4 schematically illustrates the exploded structure of a magnetic assembly and a magnetic core set thereof according to another embodiment of the present disclosure;

FIG. 5 schematically illustrates the exploded structure of a magnetic assembly and a magnetic core set thereof according to another embodiment of the present disclosure; and

FIG. 6 schematically illustrates the exploded structure of a magnetic assembly and a magnetic core set thereof according to still another embodiment of the present disclosure.

### DETAILED DESCRIPTION OF THE PREFERRED EMBODIMENT

The present disclosure will now be described more specifically with reference to the following embodiments. It is to be noted that the following descriptions of preferred embodiments of this disclosure are presented herein for purpose of illustration and description only. It is not intended to be exhaustive or to be limited to the precise form disclosed.

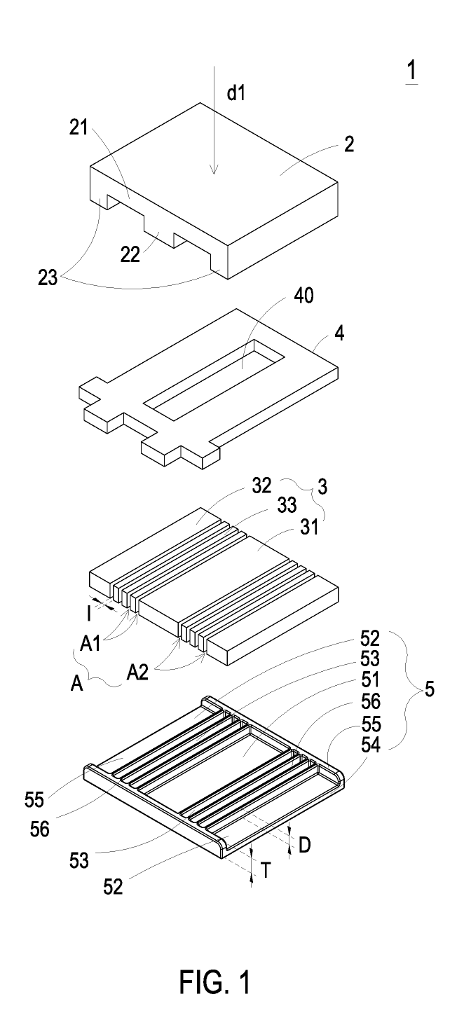

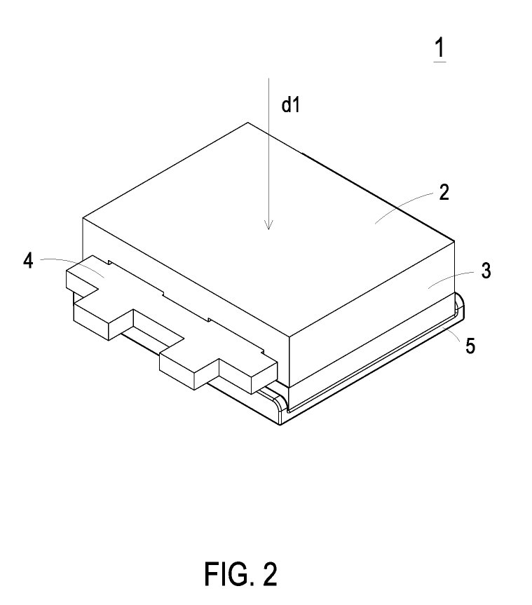

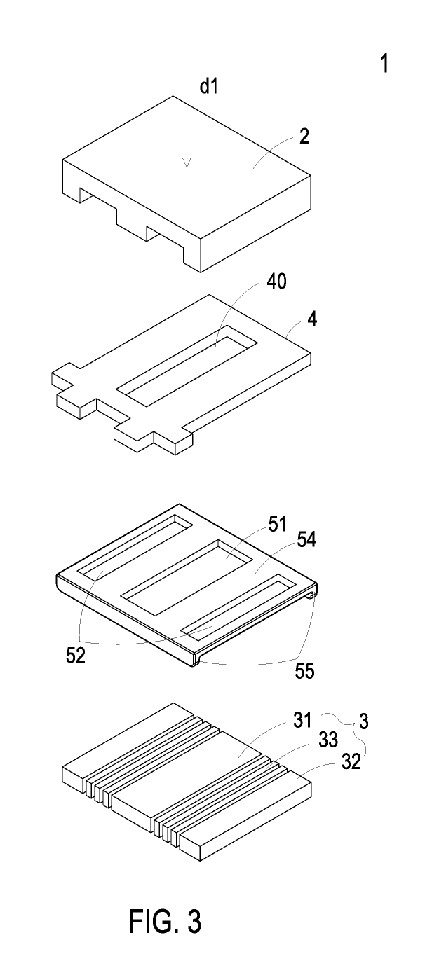

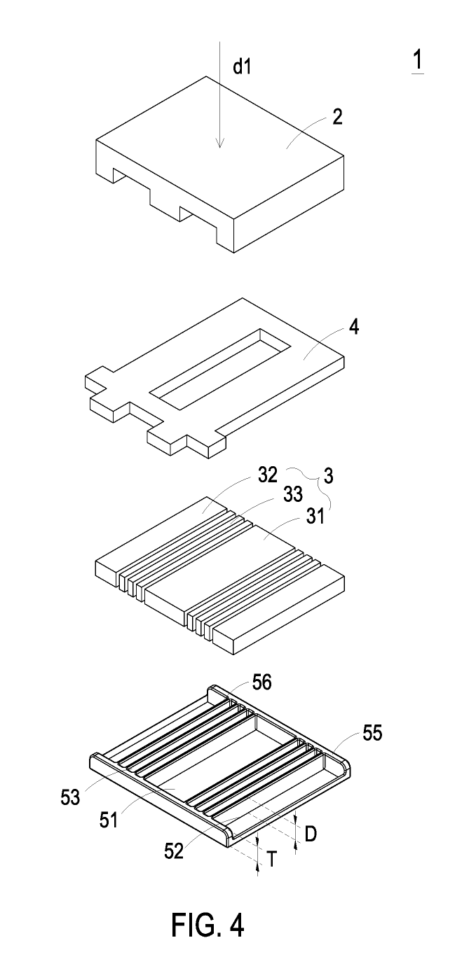

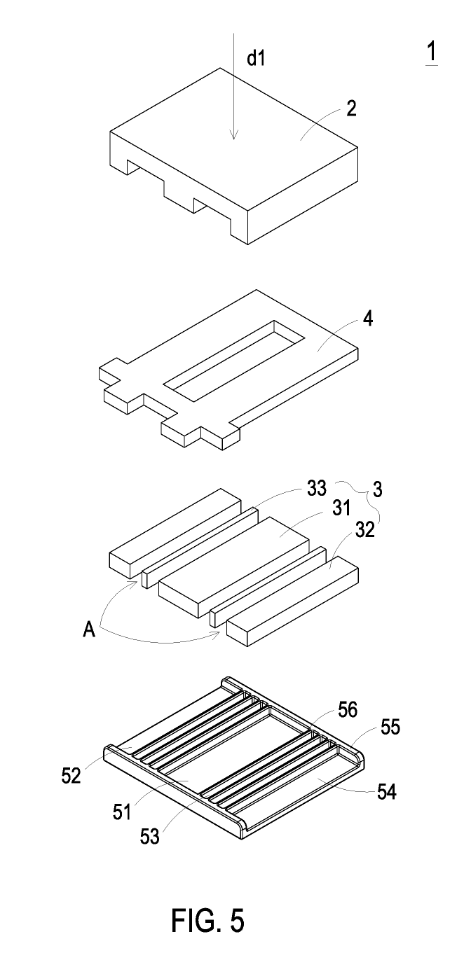

Please refer to FIG. 1, FIG. 2, FIG. 3, FIG. 4 and FIG. 5. FIG. 1 schematically illustrates the exploded structure of a magnetic assembly and a magnetic core set thereof according to an embodiment of the present disclosure. FIG. 2 schematically illustrates the structure of a magnetic assembly and a magnetic core set thereof according to an embodiment of the present disclosure. FIG. 3 schematically illustrates the exploded structure of a magnetic assembly and a magnetic core set thereof according to another embodiment of the present disclosure. FIG. 4 schematically illustrates the exploded structure of a magnetic assembly and a magnetic core set thereof according to another embodiment of the present disclosure. FIG. 5 schematically illustrates the exploded structure of a magnetic assembly and a magnetic core set thereof according to another embodiment of the present disclosure. As shown in FIG. 1, FIG. 2, FIG. 3, FIG. 4 and FIG. 5, the magnetic assembly 1 comprises a magnetic core 2, a magnetic core set 3, a circuit board 4 and a positioning plate 5. For example, the magnetic assembly 1 is a transformer or an inductor, and the magnetic core 2 is an E-shaped magnetic core, but not limited herein. Furthermore, the magnetic core 2, the magnetic core set 3, the circuit board 4 and the positioning plate 5 are stacked along a specific direction dl.

The magnetic core set 3 comprises a first magnetic member 31, two second magnetic members 32 and a plurality of third magnetic members 33. The second magnetic members 32 are disposed on two sides of the first magnetic member 31, which are better to be disposed on two sides of the first magnetic member 31 along the horizontal direction. The third magnetic members 33 are disposed between the first magnetic member and the two second magnetic members. At least one of the third magnetic members 33 is disposed between the first magnetic member 31 and one of the second magnetic members 32, and at least one of the third magnetic members 33 is disposed between the first magnetic member 31 and the other second magnetic members 32. Each of the third magnetic members 33 is disposed between the first magnetic member 31 and the two second magnetic members 32, and a plurality of separation spaces A exist between the first magnetic member 31 and the second magnetic members 32.

The circuit board 4 is disposed between the magnetic core 2 and the magnetic core set 3, and the circuit board 4 is a printed wire board (PWB), but not limited herein. The material of the positioning plate 5 is insulation material, and the positioning plate 5 has a first receptacle 51, two second receptacles 52 and a plurality of third receptacles 53. The first receptacle 51 is configured to receive the first magnetic member 31, each of the two second receptacles 52 is configured to receive one of the second magnetic members 32, and the third receptacles 53 are configured to receive the third magnetic members 33. In other words, the first magnetic member 31 is disposed in the first receptacle 51, the second magnetic members 32 are disposed in the second receptacles 52, and the third magnetic members 33 are disposed in the third receptacles 53.

In some embodiments, separation spaces disposed between the first magnetic member 31 and one of the second magnetic members 32 and the separation spaces disposed between the first magnetic member 31 and the other second magnetic member 32 have reflectional symmetry relative to the first magnetic member 31. In other words, the separation spaces A comprises a first separation space group A1 and a second separation space group A2, and the first separation space group A1 and the second separation space group A2 are symmetric to each other relative to the first magnetic member 31. For example, the magnetic core set 3 comprises a first magnetic member 31, two second magnetic members 32 and six third magnetic members 33. Three of the third magnetic members 33 are disposed on one of the two sides of the first magnetic member 31, and another three of the third magnetic members 33 are disposed on another one of the two sides of the first magnetic member 31. Furthermore, there are intervals I between the first magnetic member 31 and two of the third magnetic members 33 adjacent to the first magnetic member 31, between each two adjacent third magnetic members 33, and between the second magnetic members 32 and two of the third magnetic members 33 adjacent to the second magnetic members 32, thereby forming eight separation spaces A. That is to say, eight separation spaces A exist between the first magnetic member 31 and the two of the third magnetic members 33 adjacent to the first magnetic member 31, between each two adjacent third magnetic members 33, and between the second magnetic members 32 and two of the third magnetic members 33 adjacent to the second magnetic members 32. Among the eight separation spaces A, four of the separation spaces A at one side of the first magnetic member 31 are the first separation space group A1, another four of the separation spaces A at the other side of the first magnetic member 31 are the second separation space group A2, and the first separation space group A1 and the second separation space group A2 are symmetric to each other relative to the first magnetic member 31, but not limited herein. In some embodiments, the length of the intervals I is larger than or equal to 0.5 mm, and less than or equal to 1.2 mm, which is better to be 0.7 mm, but not limited thereto.

In brief, by disposing the magnetic core assembly comprising a first magnetic member, two second magnetic members and a plurality of third magnetic members, and making a plurality of separation spaces exist between the magnetic members, the magnetic lines are prevented from cutting through the winding, such that the eddy current loss of the magnetic assembly is reduced. Furthermore, through disposing the magnetic core in the receptacles of the positioning plate, the sizes of the separation spaces can be controlled precisely, and the separation spaces are symmetric relative to the first magnetic member of the magnetic core set and uniformly distributed.

In some embodiments, the magnetic core 2 comprises a core body 21, a middle projection 22 and two lateral projections 23. The middle projection 22 extends from the core body 21 towards the first magnetic member 31. Each of the two lateral projections 23 extends from the core body 21 towards one of the second magnetic members 32.

In some embodiments, the circuit board 4 has a slot 40, and the middle projection 22 penetrates through the slot 40. Furthermore, a winding is embedded in the circuit board 4, and the winding is disposed around the slot 40, but not limited thereto. In some embodiments, the circuit board 40 has three slots 40, and the middle projection 22 and the lateral projections 23 penetrate through the three slots 40. In some embodiments, the magnetic core 2 comprises only a core body 21 and two lateral projections 23, the circuit board 40 has two slots 40, and the lateral projections 23 penetrate through the slots 40. Moreover, two windings are embedded in the circuit board 40, and the windings are disposed around the slots 40 respectively, but not limited herein.

Therefore, by disposing the circuit board 4 embedded with windings between the magnetic core 2 and the magnetic core set 3, the space in the magnetic assembly 1 occupied by the winding is reduced, and the winding loss is decreased, such that the advantage of enhancing the effectiveness of the magnetic assembly 1 is achieved.

In some embodiments, the first receptacle 51, the second receptacles 52, and the third receptacles 53 are elongate grooves, and the widths of the first receptacle 51, the second receptacles 52 and the third receptacles 53 are identical. In some embodiments, the width of the first receptacle 51 is larger than each of the width of the second receptacles 52, and the width of each of the second receptacles 52 is larger than the width of each of the third receptacles 53. In some embodiments, the width of the first magnetic member 31 is larger than each of the width of the second magnetic members 32, and the width of each of the second magnetic members 32 is larger than each of the width of the third magnetic members 33, but not limited herein.

Please refer to FIG. 1 and FIG. 2. In some embodiments, the magnetic core set 3 is disposed between the circuit board 4 and the positioning plate 5, and the magnetic core 2, the circuit board 4, the magnetic core set 3 and the positioning plate 5 are stacked along a specific direction dl in sequence to construct a magnetic assembly 1, such that the magnetic core set 3 is disposed and positioned in the first receptacle 51, the second receptacles 52 and the third receptacles 53 of the positioning plate 5, but are not limited thereto.

Please refer to FIG. 3. In some embodiments, the positioning plate 5 is disposed between the circuit board 4 and the magnetic core set 3, and the magnetic core 2, the circuit board 4, the positioning plate 5 and the magnetic core set 3 are stacked along a specific direction dl in sequence to construct a magnetic assembly 1. Therefore, the first magnetic member 31, the second magnetic members 32 and the third magnetic members 33 are disposed and positioned in the first receptacle 51, the second receptacles 52 and the third receptacles (not shown in FIG. 3) of the positioning plate 5. Meanwhile, the magnetic core 2 and the magnetic core set 3 are separated by the positioning plate 5, thereby increasing the effects of avoiding the phenomenon of magnetic saturation.

According to the conception of the present disclosure, the positioning plate 5 has a thickness T, the first receptacle 51, each of the second receptacles 52 and each of the third receptacles 53 have an identical depth D, and the depth D is larger than zero and less than or equal to the thickness T, which means 0<D≤T. In some embodiments, as shown in FIG. 1, the depth D of the first receptacle 51, the second receptacles 52 and the third receptacles 53 of the positioning plate 5 is larger than zero and less than the thickness T, thereby disposing and positioning the magnetic members in the receptacles.

Otherwise, in some embodiments, as shown in FIG. 3, the depth D of the first receptacle 51 and the second receptacles 52 of the positioning plate 5 is equal to the thickness T, which is implemented by making the first receptacle 51 and the second receptacles 52 form as openings, such that the middle projection 22 and the lateral projections 23 of the magnetic core 2 can penetrate through first receptacle 51 and the second receptacles 52. Furthermore, each of the depth D of the third receptacles (not shown in FIG. 3) is larger than zero and less the thickness T, thereby disposing and positioning the third magnetic members 33 in the third receptacles.

Please refer to FIG. 4. In some embodiments, as shown in FIG. 4, the depth D of the first receptacle 51, the second receptacles 52 and the third receptacles 53 of the positioning plate 5 is equal to the thickness T, which is implemented by making the first receptacle 51, the second receptacles 52 and the third receptacles 53 form as openings, such that the magnetic members are disposed and positioned in the openings. Therefore, the positioning plate 5 is disposed around the magnetic core set 3 while the magnetic assembly 1 is assembled, thereby reducing the integral volume of the magnetic assembly 1.

Please refer to FIG. 5. In some embodiments, as shown in FIG. 5, the amount of the third magnetic members 33 is less than the amount of the third receptacles 53, such that each third magnetic member 33 is selectively disposed in one of the third receptacles 53, and the separation spaces A can be adjusted according to the characteristics of the desired magnetic assembly 1.

In some embodiments, the positioning plate 5 has a bottom part 54, two side walls 55 and a plurality of separation members 56. The side walls 55 are respectively disposed on two opposed sides of the bottom part 54, and the separation members 56 are disposed between the side walls 55. Furthermore, the side walls 55 are detachably connected to the bottom part 54, or the bottom part 54 is detachably connected to the separation members 56 and also the side walls 55 are detachably connected to the bottom part 54.

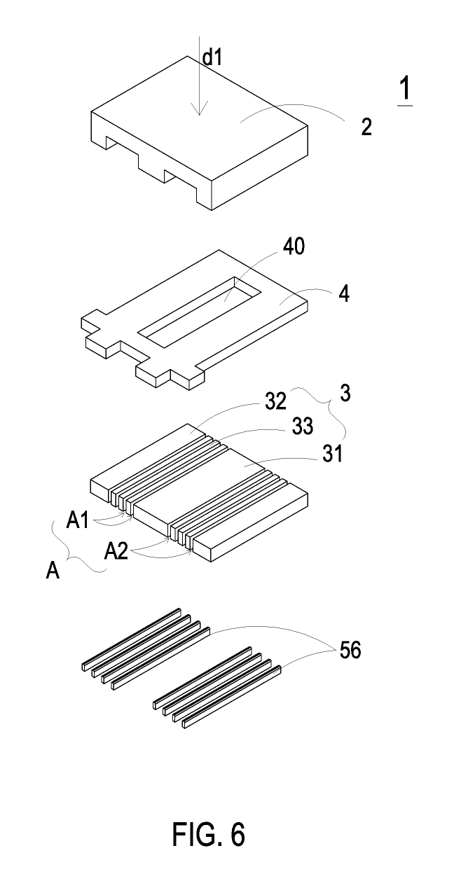

Please refer to FIG. 1, FIG. 5 and FIG. 6. FIG. 6 schematically illustrates the exploded structure of a magnetic assembly and a magnetic core set thereof according to still another embodiment of the present disclosure. As shown in FIG. 1, FIG. 5 and FIG. 6, in some embodiments, the bottom part 54 is detachably connected to the separation members 56, and the side walls 55 are detachably connected to the bottom part 54. Therefore, after the magnetic assembly 1 is assembled, the bottom part 54 and the side walls 55 of the positioning plate 5 can be detached, and separation members 56 are remained, but not limited herein. That is to say, the assembled magnetic assembly 1 comprises magnetic core 2, magnetic core set 3, circuit board 4 and separation members 56, which are disposed between the first magnetic member 31 and the second magnetic members 32, such that the volume of the magnetic assembly 1 is reduced.

In some embodiments, as shown is FIG. 3 and FIG. 4, the side walls 55 are detachably connected to the bottom part 54, such that the side walls 55 can be detached after the magnetic assembly 1 is assembled, thereby reducing the volume of the magnetic assembly 1, but not limited thereto.

From the above description, the present disclosure provides a magnetic assembly and a magnetic core set thereof. By disposing the magnetic core set comprising a first magnetic member, two second magnetic members and a plurality of third magnetic members, and making a plurality of separation spaces exist between the magnetic members, the magnetic lines are prevented from cutting through the winding, such that the eddy current loss of the magnetic assembly is reduced. Furthermore, through disposing the magnetic core set in the receptacles of the positioning plate, the sizes of the separation spaces can be controlled precisely, and the separation spaces are symmetric relative to the first magnetic member of the magnetic core set and uniformly distributed. Meanwhile, by disposing a circuit board embedded with a winding between the magnetic core and the magnetic core set, the space in the magnetic assembly occupied by the winding is reduced, and the winding loss is decreased, such that the advantage of enhancing the effectiveness of the magnetic assembly is achieved. In addition, through disposing the detachable bottom part and side walls on the positioning plate, the bottom part and the side walls can be detached after the magnetic assembly is assembled, thereby reducing the volume of the magnetic assembly.

While the disclosure has been described in terms of what is presently considered to be the most practical and preferred embodiments, it is to be understood that the disclosure needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A magnetic assembly, comprising:
a magnetic core;
a magnetic core set, comprising:
a first magnetic member;
two second magnetic members disposed on two sides of the first magnetic member; and
a plurality of third magnetic members disposed between the first magnetic member and the two second magnetic members, wherein at least one of the third magnetic members is disposed between the first magnetic member and one of the second magnetic members, at least one of the third magnetic members is disposed between the first magnetic member and the other second magnetic member; wherein a plurality of separation spaces exist between the first magnetic member and the second magnetic members;
a circuit board disposed between the magnetic core and the magnetic core set; and
a positioning plate having a first receptacle configured to receive the first magnetic member, two second receptacles each configured to receive one of the second magnetic members and a plurality of third receptacles configured to receive the third magnetic members.

2. The magnetic assembly according to claim 1, wherein the magnetic core comprises a core body; a middle projection extending from the core body towards the first magnetic member; and two lateral projections each extending from the core body towards one of the second magnetic members.

3. The magnetic assembly according to claim 2, wherein the circuit board has a slot, and the middle projection penetrates through the slot.

4. The magnetic assembly according to claim 2, wherein the circuit board has two slots, and the lateral projections penetrate through the slots.

5. The magnetic assembly according to claim 1, wherein the separation spaces disposed between the first magnetic member and one of the second magnetic members and the separation spaces disposed between the first magnetic member and the other second magnetic member have reflectional symmetry relative to the first magnetic member.

6. The magnetic assembly according to claim 1, wherein the first receptacle, the second receptacles, and the third receptacles are elongate grooves, and wherein the widths of the first receptacle, the second receptacles and the third receptacles are identical.

7. The magnetic assembly according to claim 1, wherein the first receptacle, the second receptacles, and the third receptacles are elongate grooves, and wherein the width of the first receptacle is larger than the width of each of the second receptacles, and the width of each of the second receptacles is larger than the width of each of the third receptacles.

8. The magnetic assembly according to claim 1, wherein the width of the first magnetic member is larger than the width of each of the second magnetic members.

9. The magnetic assembly according to claim 8, wherein the width of each of the second magnetic members is larger than the width of each of the third magnetic members.

10. The magnetic assembly according to claim 1, wherein the magnetic core, the magnetic core set, the circuit board and the positioning plate are stacked.

11. The magnetic assembly according to claim 10, wherein the magnetic core set is disposed between the circuit board and the positioning plate.

12. The magnetic assembly according to claim 10, wherein the positioning plate is disposed between the circuit board and the magnetic core set.

13. The magnetic assembly according to claim 1, wherein the positioning plate has a thickness, and the first receptacle, each of the second receptacles and each of the third receptacles have an identical depth, wherein the depth is larger than zero and less than or equal to the thickness.

14. The magnetic assembly according to claim 1, wherein the amount of the third magnetic members is less than the amount of the third receptacles, such that each third magnetic member is selectively disposed in one of the third receptacles.

15. The magnetic assembly according to claim 1, wherein the positioning plate has a bottom part, two side walls and a plurality of separation members, the side walls are respectively disposed on two opposed sides of the bottom part, and the separation members are disposed between the side walls, wherein the side walls are detachably connected to the bottom part.

16. The magnetic assembly according to claim 15, wherein the bottom part is detachably connected to the separation members.

17. A magnetic core set, comprising:
a first magnetic member;
two second magnetic members disposed on two sides of the first magnetic member; and
a plurality of third magnetic members disposed between the first magnetic member and the two second magnetic members, wherein at least one of the third magnetic members is disposed between the first magnetic member and one of the second magnetic members, at least one of the third magnetic members is disposed between the first magnetic member and the other second magnetic member; wherein a plurality of separation spaces exist between the first magnetic member and the second magnetic members.

18. A magnetic assembly, comprising:
a magnetic core;
a magnetic core set, comprising:
a first magnetic member;
two second magnetic members disposed on two sides of the first magnetic member; and
a plurality of third magnetic members disposed between the first magnetic member and the two second magnetic members, wherein at least one of the third magnetic members is disposed between the first magnetic member and one of the second magnetic members, at least one of the third magnetic members is disposed between the first magnetic member and the other second magnetic member; wherein a plurality of separation spaces exist between the first magnetic member and the second magnetic members;
a circuit board disposed between the magnetic core and the magnetic core set; and
a plurality of separation members disposed between the first magnetic member and the second magnetic members.
